(19) United States
(12) Patent Application Publication
(10) Pub. No.: US 2023/0038805 A1
(43) Pub. Date: Feb. 9, 2023

(54) METHODS, SYSTEMS, APPARATUS, AND ARTICLES OF MANUFACTURE TO CONTROL LOAD DISTRIBUTION OF INTEGRATED CIRCUIT PACKAGES

(71) Applicant: Intel Corporation, Santa Clara, CA (US)

(72) Inventors: Phil Geng, Washougal, WA (US); David Shia, Portland, OR (US); Ralph Miele, Hillsboro, OR (US); Sandeep Ahuja, Portland, OR (US); Jeffory Smalley, East Olympia, WA (US)

(21) Appl. No.: 17/956,624

(22) Filed: Sep. 29, 2022

(51) Int. Cl. H01L 23/367; H01L 23/433; H01L 23/40

(52) U.S. Cl. CPC H01L 23/3672; H01L 23/433; H01L 23/4006; H01L 2023/4087

(57) ABSTRACT

Methods, systems, apparatus, and articles of manufacture to control load distribution of integrated circuit packages are disclosed. An example apparatus includes a heatsink, a base of the heatsink to be thermally coupled to a semiconductor device, and a rigid plate to be coupled to the semiconductor device and the base of the heatsink, the rigid plate stiffer than the base, the rigid plate distinct from a bolster plate to which the heatsink is to be coupled.

### FIELD OF THE DISCLOSURE

This disclosure relates generally to integrated circuit packages and, more particularly, to methods, systems, apparatus, and articles of manufacture to control load distribution of integrated circuit packages.

### BACKGROUND

In many electronic devices, a heatsink is mechanically and thermically coupled to a semiconductor device (e.g., an integrated circuit (IC) package, a land grid array (LGA) processor chip, a ball grid array (BGA) processor chip, a pin grid array (PGA) processor chip, a memory chip, etc.) to dissipate heat therefrom. A carrier (e.g., a package carrier) can be used to couple the heatsink to the semiconductor device and/or align the semiconductor device to a corresponding socket during assembly.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 illustrates an exploded view of an electronic heat dissipating component stack in which examples disclosed herein may be implemented.

FIG. 18 illustrates a simplified side view of the heat dissipating component stack of FIG. 17 in which the carrier of FIG. 17 is absent.

FIG. 19A illustrates a front view of an example heatsink of FIGS. 17 and/or 18.

FIG. 19B illustrates a side view of the example heatsink of FIGS. 17 and/or 18.

FIG. 20 illustrates delamination of the example base from the example fins of the heatsink of FIGS. 19A and/or 19B.

FIG. 21 illustrates an example electronic heat dissipating component stack constructed in accordance with teachings of this disclosure.

FIG. 22 illustrates a plan view of the example plate of FIG. 21.

FIG. 23 illustrates an example stiffener plate that may be implemented in the example component stack of FIG. 21 in addition to or instead of the example plate of FIGS. 21 and/or 22.

FIG. 24A illustrates a plan view of the example stiffener plate of FIG. 23 having a first example cross-sectional shape.

FIG. 24B illustrates a plan view of the example stiffener plate of FIG. 23 having a second example cross-sectional shape.

FIG. 24C illustrates a plan view of the example stiffener plate of FIG. 23 having a third example cross-sectional shape.

FIG. 24D illustrates a plan view of the example stiffener plate of FIG. 23 having a fourth example cross-sectional shape.

FIG. 25 is a flowchart representative of an example method of assembling the example electronic component stack of FIG. 21 including the example plate of FIG. 21.

FIG. 26 is a flowchart representative of an example method of assembling the example electronic component stack of FIG. 21 including the example stiffener plate of FIG. 23.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

During operation of an electronic device, one or more electronic components (e.g., an LGA processor chip, a BGA, processor chip, a PGA processor chip, a memory chip, other types of integrated circuit (IC) packages or semiconductor devices, etc.) of the electronic device may generate heat. In some cases, excessive heat may cause overheating and, thus, degradation in performance of the electronic components. To prevent overheating, some electronic devices include a heatsink thermally coupled to one or more of the electronic components to facilitate heat transfer therefrom. Some heatsinks utilize liquids and/or gases (e.g., air) to cool the electronic components.

In some electronic devices, the heatsink and a semiconductor device (e.g., a CPU, a GPU, or other IC package) being cooled thereby are assembled in an electronic heat dissipating component stack that further includes a corresponding socket to receive and electrically couple to the semiconductor device. The socket is electrically and mechanically coupled to a top surface of a printed circuit board (PCB). Further, the component stack may include a carrier coupled between the semiconductor device and the heatsink to facilitate alignment of the semiconductor device to the socket during assembly. In some cases, to prevent decoupling of the semiconductor device from the socket, one or more springs (e.g., retention springs) are coupled to a base of the heatsink and a bolster plate on the top surface of the PCB. The springs generate a downward force on the base of the heatsink, which presses the semiconductor device downward into and/or against the socket to enable retention therein and ensure adequate contact between different electrical contacts of the socket and semiconductor device. Further, the semiconductor device generates an upward force on the base of the heatsink (as a reactive force to the downward compressive force). In some cases, a combination of the upward and downward forces on the base causes bending or warpage of the elements within the component stack. In some such cases, bending may result in delamination (e.g., separation) of the base of the heatsink from fins of the heatsink at the edges of the base. Such delamination degrades efficiency of heat transfer from the semiconductor device to the heatsink, thus resulting in ineffective cooling of the semiconductor device.

Some known techniques to prevent delamination include altering a material used for the base of the heatsink and/or using a different method for coupling the fins of the heatsink to the base of the heatsink. For instance, some heatsinks utilize materials having increased stiffness to reduce bending due to external loads. However, such materials may be prone to creep and/or have reduced heat transfer efficiency. Alternatively, welding the fins to the base and/or increasing the temperature of solder used to couple the fins to the base may improve bonding strength therebetween. However, such methods may increase manufacturing complexity and/or cost associated with manufacturing the heatsink.

Examples disclosed herein reduce and/or prevent delamination between fins and a base of a heatsink by providing an example plate (e.g., a load plate, a stiffener plate) on a bottom surface of the base. A first surface of the example plate disclosed herein is attached (e.g., fastened, secured) to the base via one or more fasteners, and one or more springs (e.g., retention springs) are provided to urge a second surface of the plate toward a bolster plate of a PCB. An example semiconductor device is disposed in an aperture of the plate and thermally coupled to the base of the heatsink such that heat may be transferred from the semiconductor device to the heatsink. In some examples, the semiconductor device is coupled to the plate via one or more carrier snaps spaced about the aperture. In some examples, the plate increases stiffness of the base of the heatsink and/or distributes loads from the semiconductor device and/or the springs across a surface of the base to reduce bending of the base. Accordingly, by reducing bending of the base, the plate reduces and/or prevents delamination between the fins and the base of the heatsink. Advantageously, examples disclosed herein help to preserve efficiency of heat transfer from electronic components to the heatsink and, thus, prevent overheating of the electronic components.

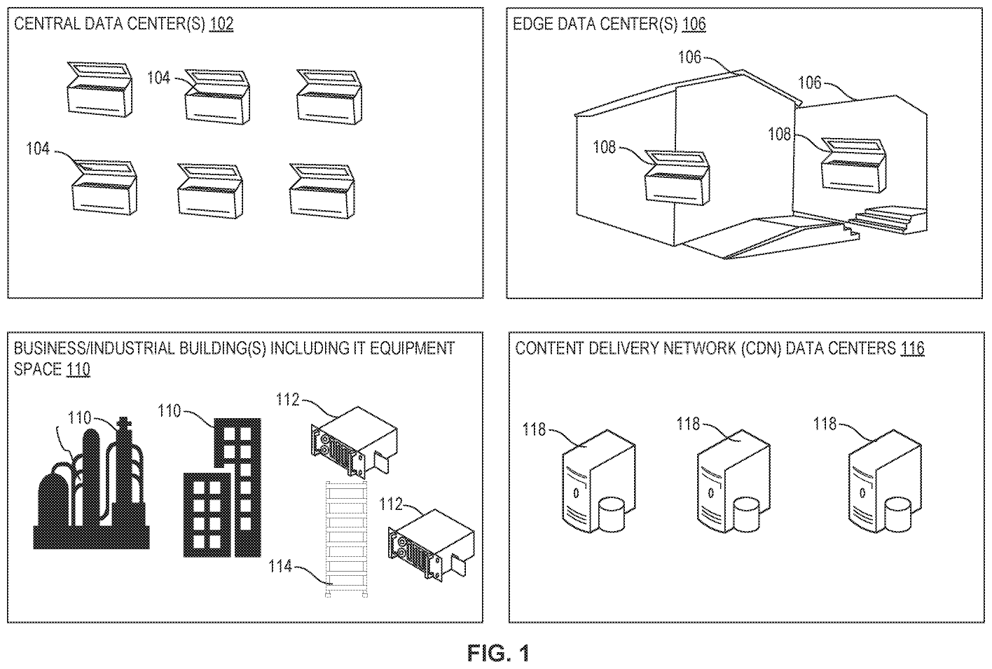

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

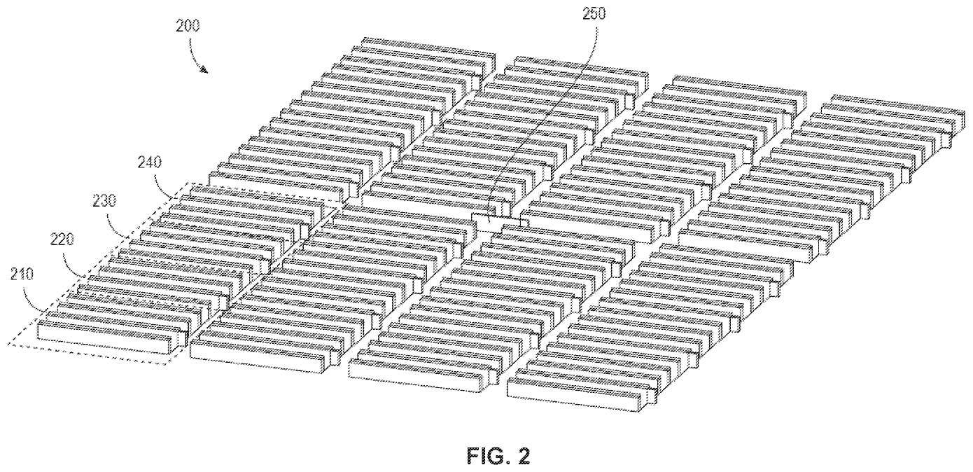

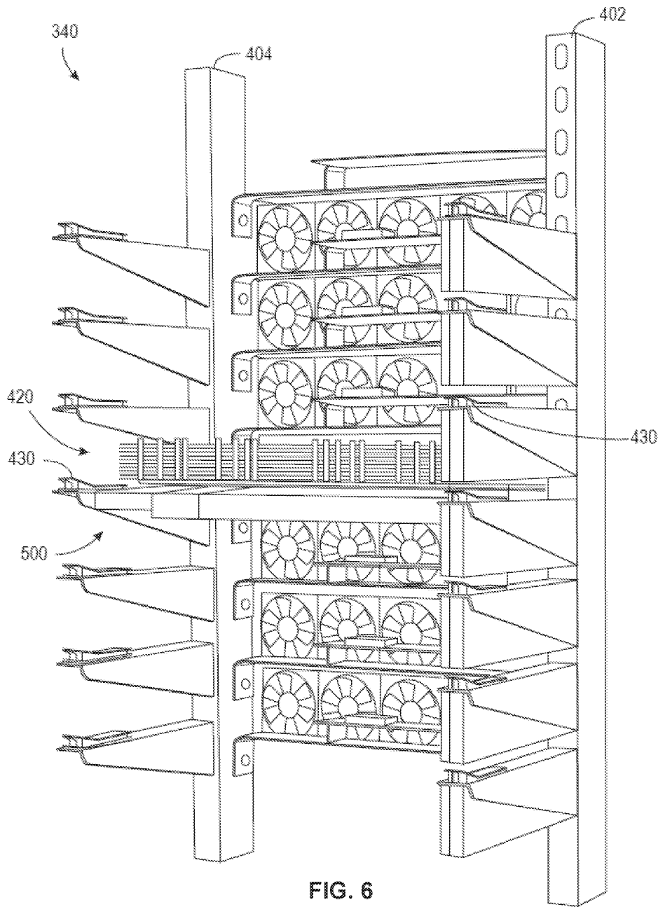

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

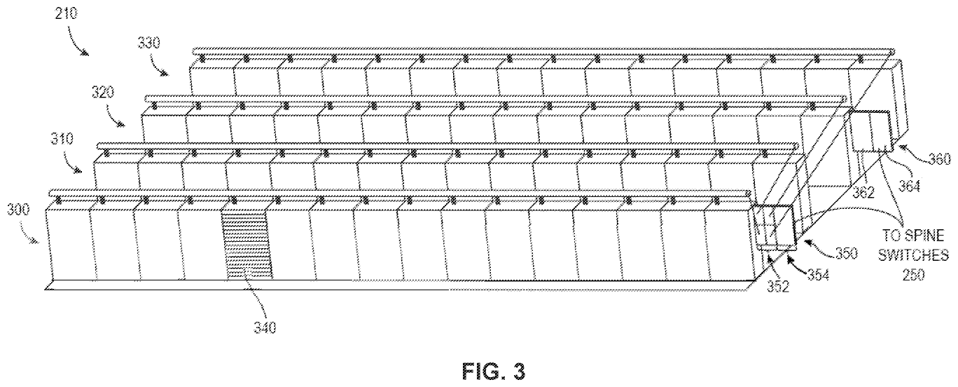

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

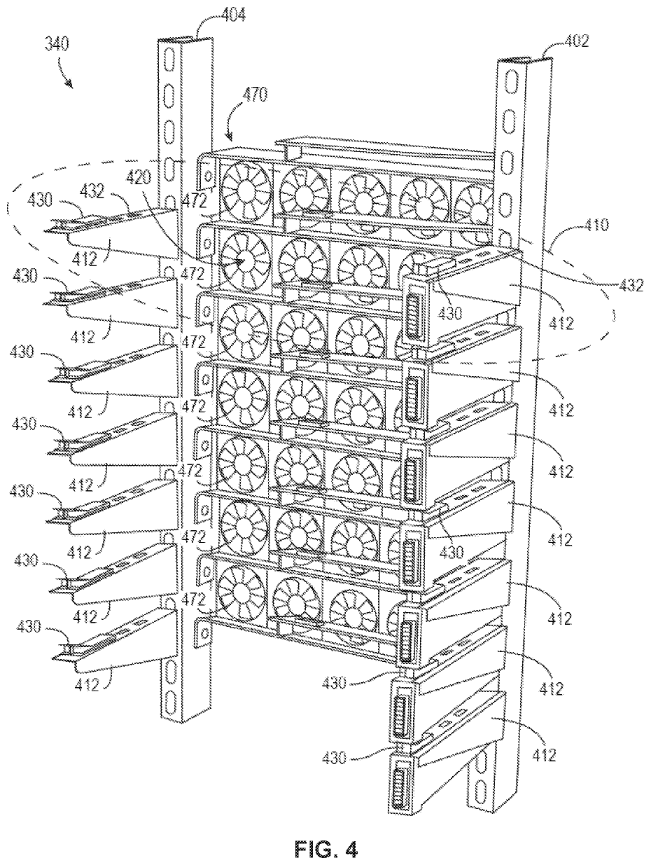

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

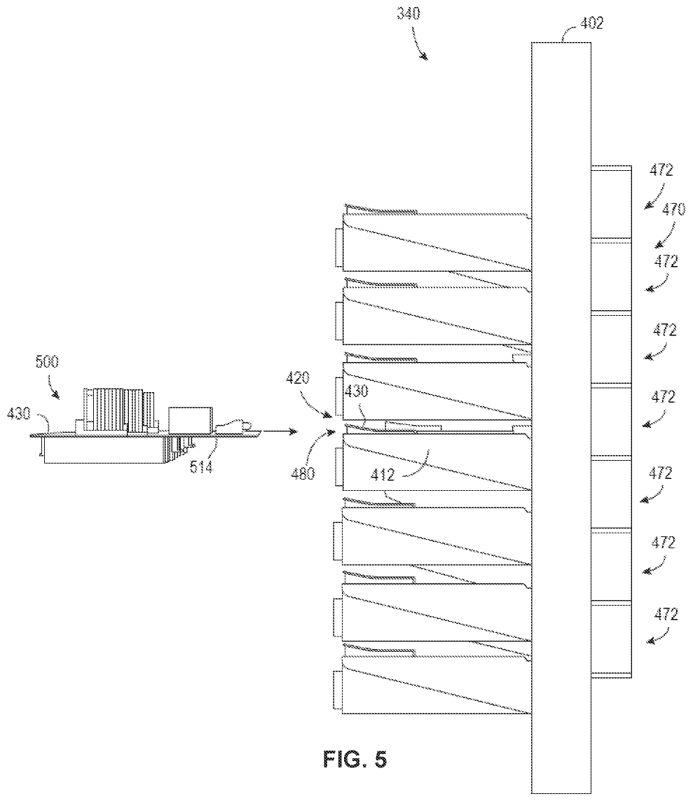

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

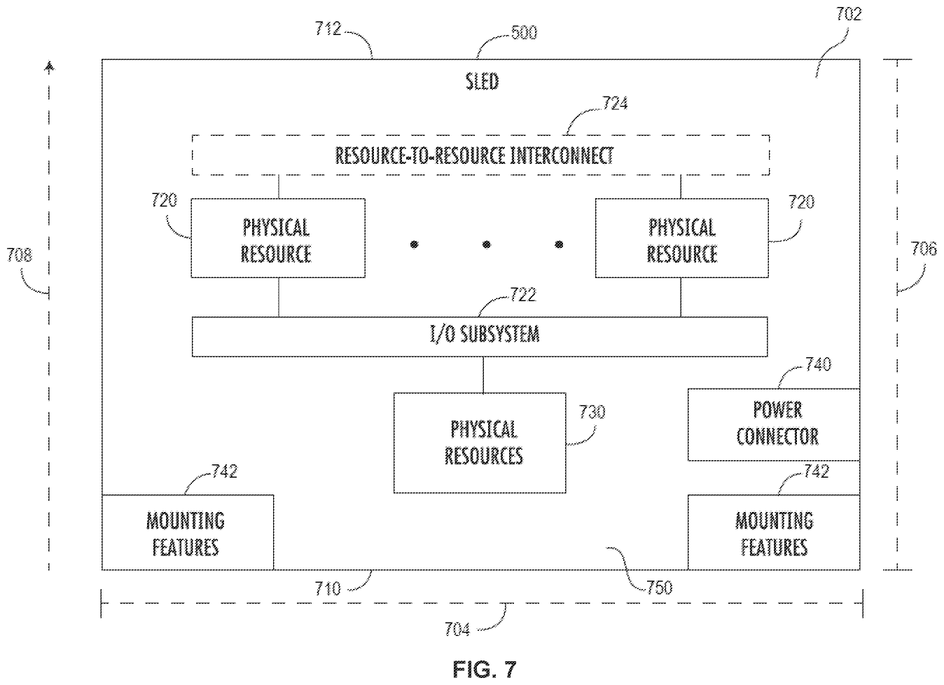

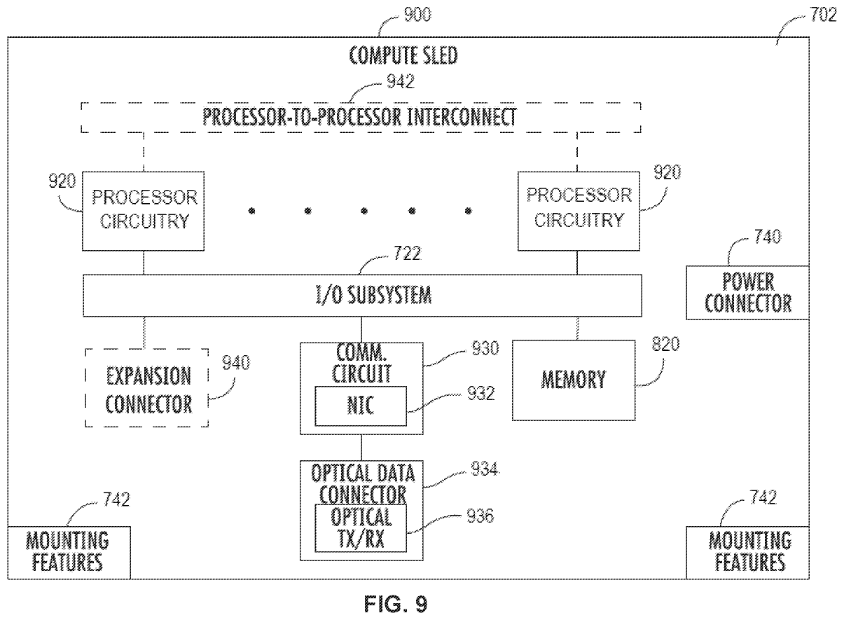

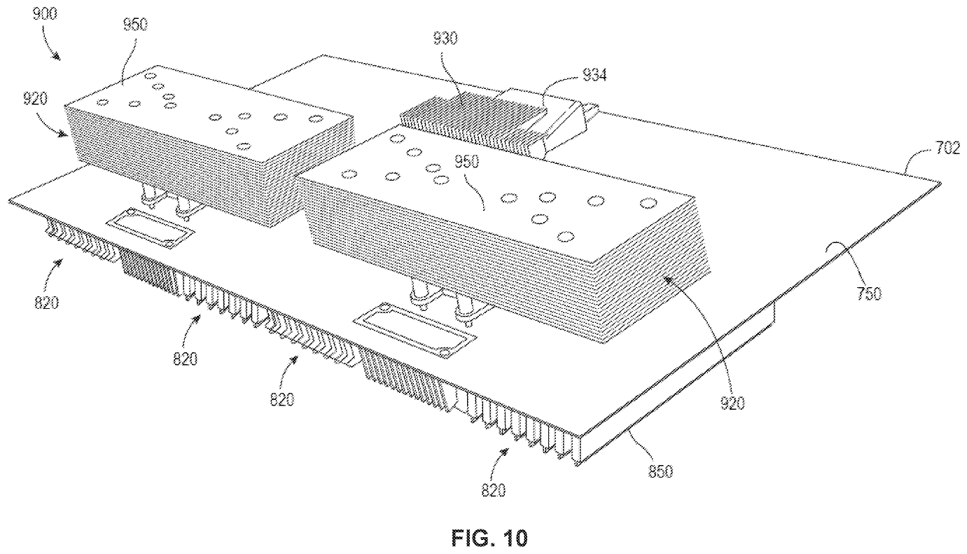

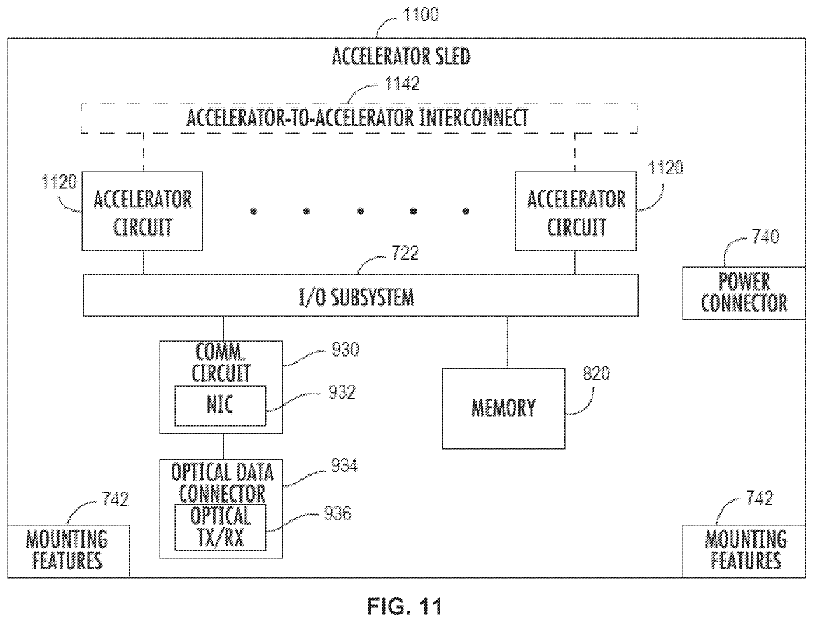

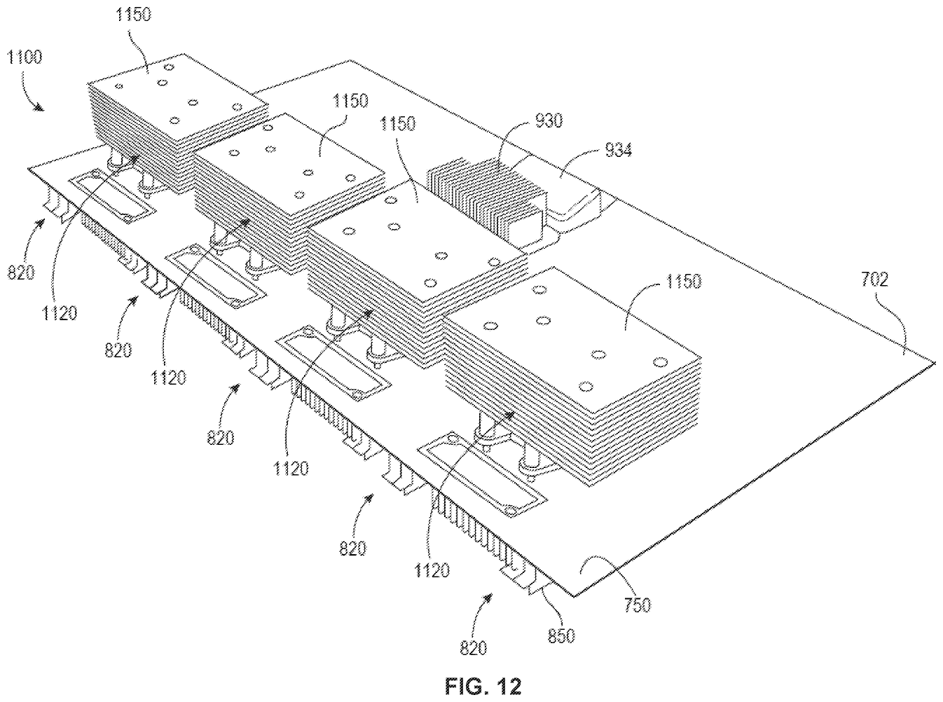

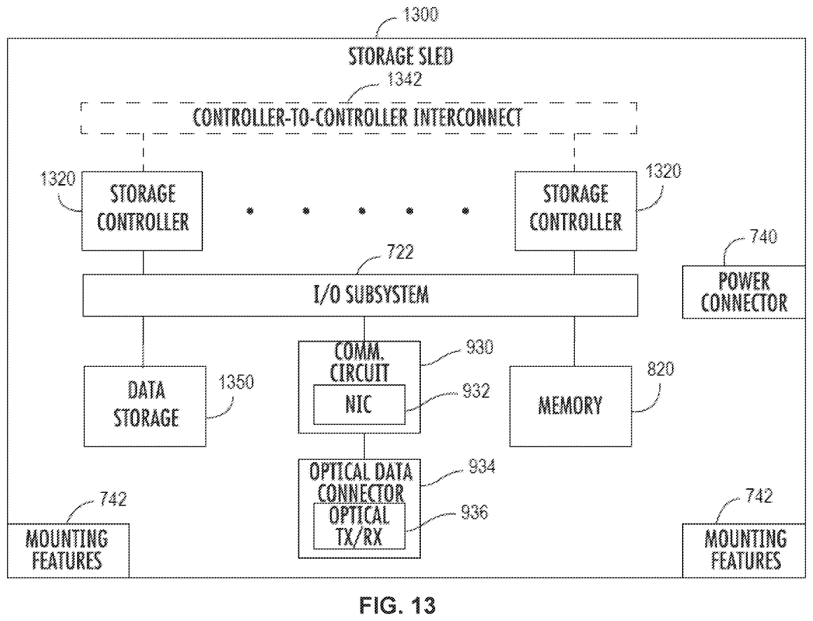

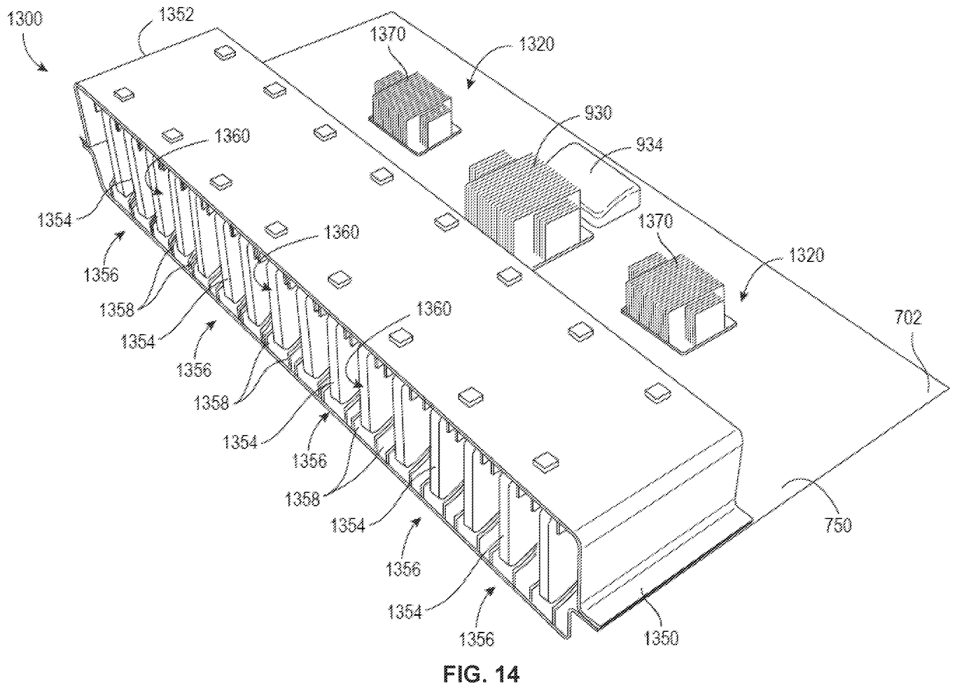

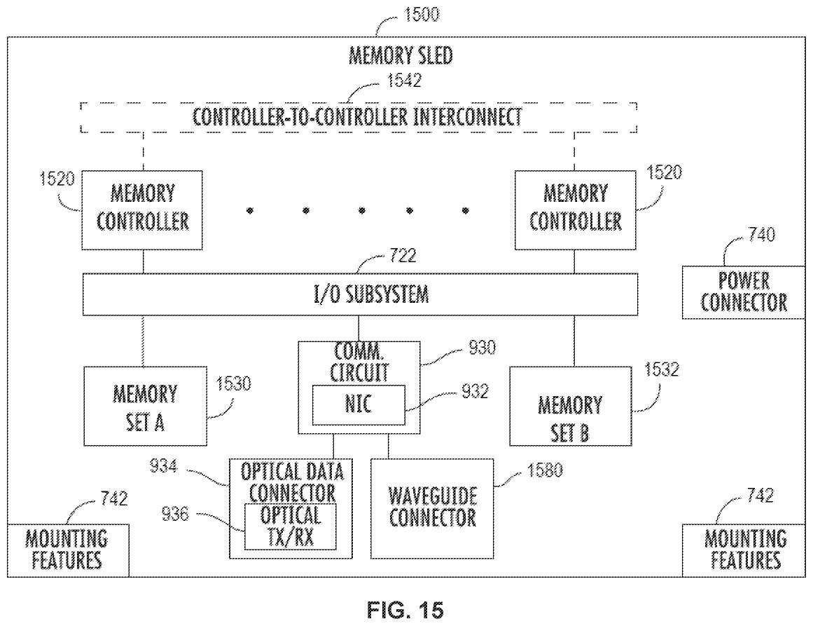

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase immersion cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

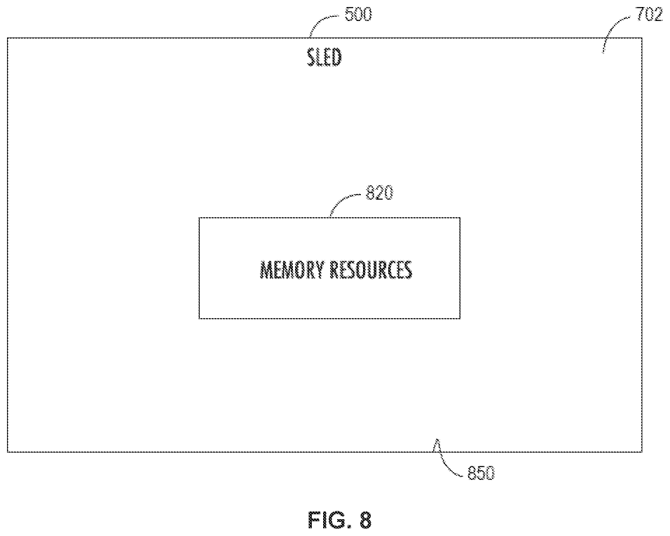

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

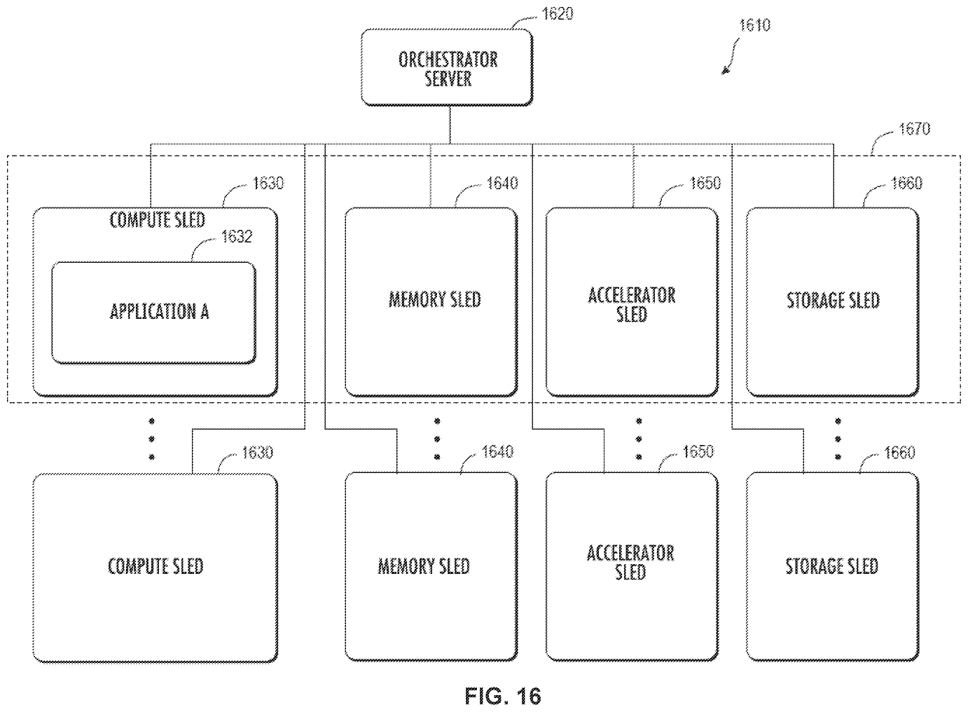

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

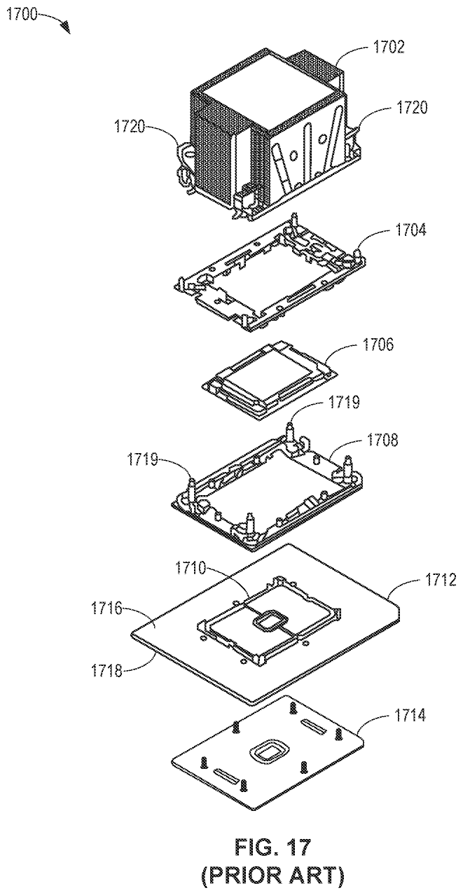

FIG. 17 illustrates an exploded view of an electronic heat dissipating component stack 1700 in which examples disclosed herein may be implemented. In FIG. 17, the component stack 1700 includes a heatsink 1702, a carrier (e.g., a package carrier, a carrier plate) 1704, a semiconductor device 1706, a bolster plate 1708, a socket 1710 coupled (e.g., soldered) to a printed circuit board (PCB) (e.g., a motherboard) 1712, and a backplate 1714.

In FIG. 17, the heatsink 1702 is couplable (e.g., thermally couplable) to the semiconductor device 1706 to dissipate heat therefrom. In some cases, the heatsink 1702 corresponds to one of the heatsinks 950 of FIG. 10, one of the heatsinks 1150 of FIG. 12, or one of the heatsinks 1370 of FIG. 14. In FIG. 17, the semiconductor device 1706 is a land grid array (LGA) processor chip. Additionally or alternatively, the semiconductor device 1706 can be one of a ball grid array (BGA) processor chip or a pin grid array (PGA) processor chip instead. Further, in some examples, other types of IC packages can be used in the component stack 1700 instead of a processor chip (e.g., a memory chip). In FIG. 17, the carrier 1704 is used to couple the heatsink 1702 to the semiconductor device 1706.

In some cases, a subassembly including the heatsink 1702, the carrier 1704, and the semiconductor device 1706 can be electrically and/or mechanically coupled to a top surface 1716 of the underlying PCB 1712 using the bolster plate 1708 and/or the socket 1710. For instance, the bolster plate 1708 is couplable to the top surface of the PCB 1712 such that the socket 1710 is centrally disposed in the bolster plate 1708. In FIG. 17, the carrier 1704 includes one or more alignment features (e.g., holes, studs, and/or pins) that mate to corresponding alignment features (e.g., holes, studs, and/or pins) of the bolster plate 1708. During assembly of the subassembly (e.g., the heatsink 1702, the carrier 1704, and the semiconductor device 1706) to the PCB 1712, the mating of the alignment features between the carrier 1704 and the bolster plate 1708 facilitates alignment of contacts between the semiconductor device 1706 and corresponding contacts of the socket 1710. As such, the semiconductor device 1706 can be electrically and/or mechanically coupled to the socket 1710 without damage to the semiconductor device 1706 and/or the socket 1710. Further, the backplate 1714 is couplable to the bolster plate 1708 through holes in the PCB 1712 such that the backplate 1714 is adjacent a bottom surface 1718 of the PCB 1712 and the bolster plate 1708 is adjacent the top surface 1716 of the PCB 1712 with the PCB 1712 sandwiched therebetween. In FIG. 17, the bolster plate 1708 further includes posts 1719 that extend into and are captured by and/or connected to fasteners (e.g., spring-loaded fasteners) 1720 positioned at the corners of the heatsink 1702. In FIG. 17, the bolster plate 1708 includes springs couplable to the heatsink 1702 to urge the heatsink 1702 toward the bolster plate 1708. When the component stack 1700 is assembled, the springs urge the heatsink 1702 toward the bolster plate 1708 to place the semiconductor device 1706 and socket 1710 in compression. Thus, the spring force from the springs urges the semiconductor device 1706 toward the socket 1710 and facilitates retention therein. Additionally or alternatively, the springs can be implemented in the fasteners 1720, such that the springs in the fasteners 1720 urge the heatsink 1720 toward the bolster plate 1708 when the posts 1917 are connected to the fasteners 1720. In some examples, the backplate 1714 can include posts (e.g., similar to the posts 1719) that extend through the bolster plate and a base of the heatsink 1702 to be captured by and/or connected to the fasteners 1720 including the springs. In other examples, the fasteners 1720 can additionally or alternatively be positioned adjacent the backplate 1714 to capture and/or connect to posts extending through the assembly from the heatsink 1702.

In this instance, the carrier 1704 is used to couple the heatsink 1702 to the semiconductor device 1706 and/or to facilitate alignment between the semiconductor device 1706 and the socket 1710 during assembly. However, in many typical component stacks (such as that shown in FIG. 17), the carrier 1704 does not perform a function after assembly of the semiconductor device 1706 and the socket 1710. In particular, once the component stack 1700 of FIG. 17 is assembled, the carrier 1704 does not provide significant structural support to the component stack 1700.

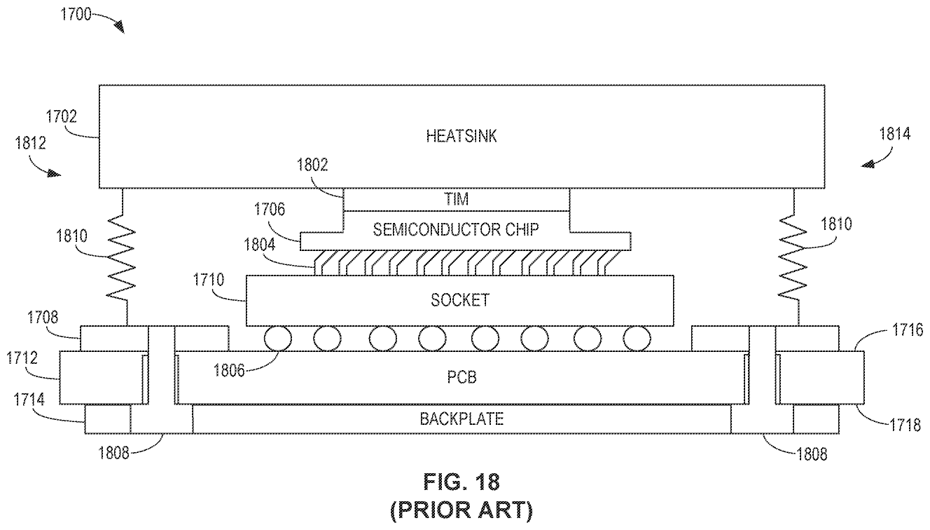

FIG. 18 illustrates a simplified side view of the example component stack 1700 of FIG. 17, in which the carrier 1704 of FIG. 17 is absent. In FIG. 18, the semiconductor device 1706 is coupled to the heatsink 1702 via a thermal interface material (TIM) 1802 which can be, for instance, grease. In this instance, the TIM 1802 dissipates heat and/or facilitates heat transfer from the semiconductor device 1706. In FIG. 18, the semiconductor device 1706 is electrically and/or mechanically coupled to the socket 1710 via a first array of interconnects (e.g., pins) 1804, and the socket 1710 is further electrically and/or mechanically coupled to the PCB 1712 via a second array of interconnects (e.g., balls) 1806 on the top surface 1716 of the PCB 1712. The backplate 1714 is coupled to the bottom surface 1718 of the PCB 1712 and to the bolster plate 1708 via fasteners (e.g., bolts, screws, threaded fasteners) 1808 extending through the PCB 1712 and/or the bolster plate 1708.

In FIG. 18, the spring force urging the heatsink 1702 towards the bolster plate 1708 to place the semiconductor device 1706 and the socket 1710 in compression is illustratively represented by springs 1810 for purposes of explanation. However, as noted above, the springs 1810 may positioned in different locations (e.g., within the fasteners 1720 above a base of the heatsink 1702, below and/or adjacent the backplate 1714, on the bolster plate 1708, between the bolster plate 1708 and the heatsink 1702, etc.). In this case, the springs 1810 are positioned proximate outer ends 1812, 1814 of the heatsink 1702 and/or the bolster plate 1708 (e.g., away from a central region of the heatsink 1702 and/or the bolster plate 1708). In this instance, the springs 1810 urge the heatsink 1702 towards the bolster plate 1708. As a result, the heatsink 1702 presses downward in FIG. 18 on the semiconductor device 1706 to hold the semiconductor device 1706 towards the socket 1710, thus reducing a likelihood of decoupling of the semiconductor device 1706 from the socket 1710.

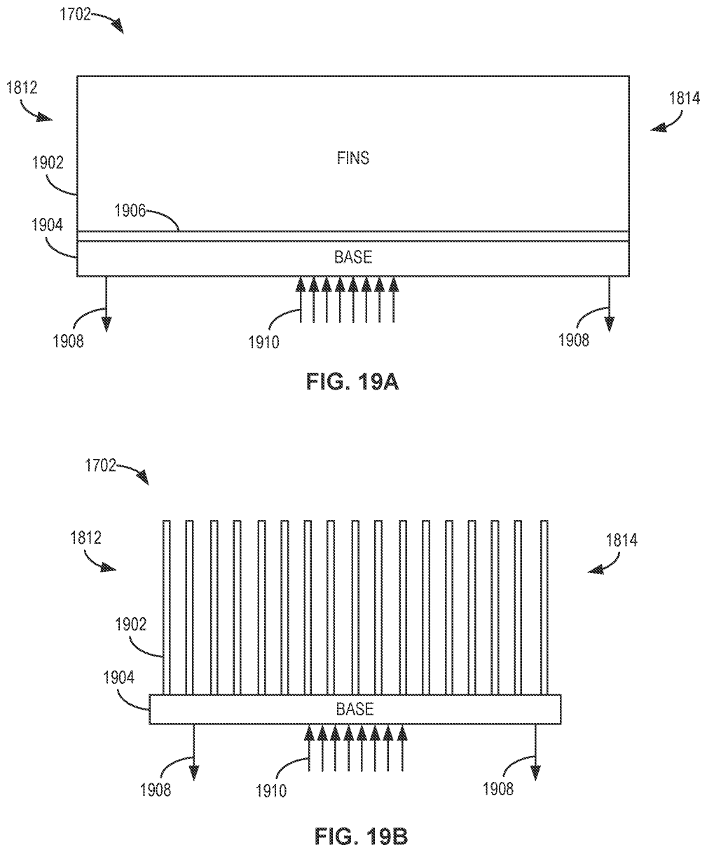

FIGS. 19A and 19B illustrate a front view and a side view, respectively, of the heatsink 1702 of FIGS. 17 and/or 18. In FIGS. 19A and 19B, the heatsink 1702 includes fins (e.g., heatsink fins) 1902 coupled to a base (e.g., a heatsink base) 1904. In some examples, the fins 1902 are L-shaped. In FIG. 19A, the fins 1902 are coupled to the base 1904 using solder material 1906. Additionally or alternatively, the fins 1902 may be coupled to the base 1904 via a different coupling method (e.g., providing an adhesive layer, welding, etc.). In some examples, heat from the semiconductor device 1706 of FIGS. 17 and/or 18 is transferred from the base 1904 to the fins 1902, and the heat is dissipated to a cooling fluid (e.g., air, liquid coolant) surrounding and/or flowing across the fins 1902.

In FIGS. 19A and 19B, downward forces (e.g., tensile forces) 1908 act on the base 1904 at locations proximate the outer ends 1812, 1814 of the heatsink 1702 at which the springs 1810 of FIG. 18 are coupled to the base 1904. In particular, the springs 1810 of FIG. 18 generate the downward forces 1908 on the base 1904 to urge the heatsink 1702 downward toward the bolster plate 1708 of FIGS. 17 and/or 18. Further, as the heatsink 1702 presses downward onto the semiconductor device 1706, the semiconductor device 1706 in turn generates upward forces (e.g., reactive forces) 1910 on the base 1904. In this instance, the semiconductor device 1706 and, thus, the upward forces 1910 are centrally positioned with respect to the base 1904.

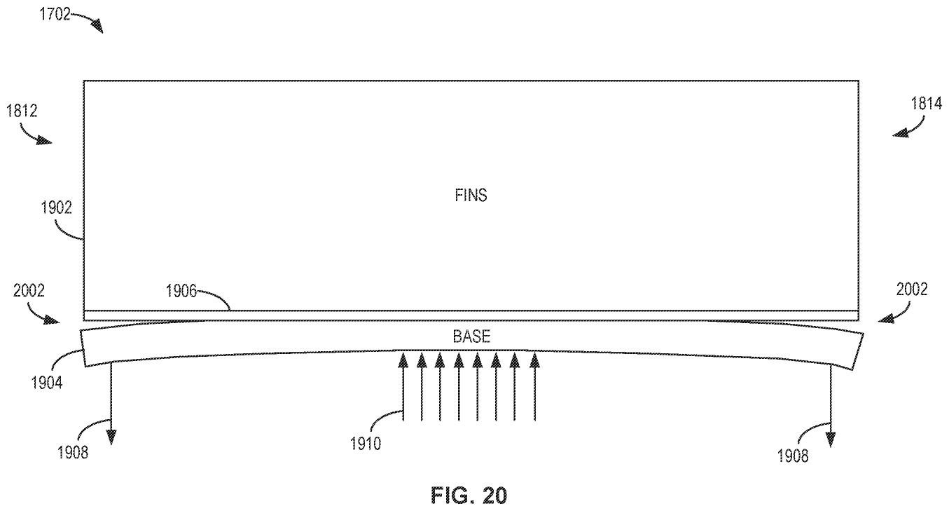

FIG. 20 illustrates delamination of the base 1904 from the fins 1902 of the heatsink 1702 of FIG. 19A. In some instances, a combination of the upward forces 1910 acting centrally on the base 1904 and the downward forces 1908 acting proximate the outer ends 1812, 1816 of the base 1904 results in the delamination shown in FIG. 20. In particular, the downward forces 1908 cause the base 1904 to detach from the fins 1902 and/or the solder material 1906 at the outer ends 1812, 1814 of the base 1904, resulting in gaps 2002 between the base 1904 and the fins 1902. In some cases, such delamination may reduce effectiveness of the heatsink 1702 in dissipating heat from the semiconductor device 1706 of FIGS. 17 and/or 18. Further, the delamination may reduce contact loads between electrical contacts of the semiconductor device 1706 and the corresponding socket 1710, thus disrupting and/or preventing transmission of electrical signals therebetween. In some cases, repair and/or replacement of the heatsink 1702 may be required when such delamination occurs, thus increasing parts and/or manufacturing costs associated with the component stack 1700 of FIGS. 17 and/or 18.

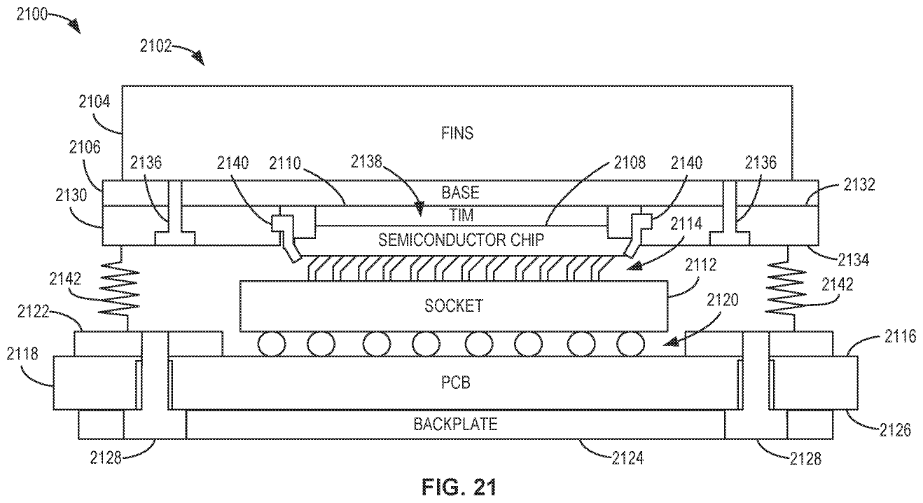

FIG. 21 illustrates an example heat dissipating component stack 2100 constructed in accordance with teachings of this disclosure. In the illustrated example of FIG. 21, the component stack 2100 includes an example heatsink 2102 including example fins 2104 coupled to an example base 2106. In this example, an example semiconductor device (e.g., an LGA processor chip, a BGA processor chip, a PGA processor chip, a memory chip) 2108 is thermally and/or mechanically coupled to the base 2106 via example TIM 2110. Further, the semiconductor device 2108 is electrically and/or mechanically coupled to an example socket 2112 using a first example array of interconnects (e.g., pins) 2114, and the socket 2112 is electrically and/or mechanically coupled to an example top surface 2116 of an example PCB 2118 using a second example array of interconnects (e.g., balls) 2120. The PCB 2118 is coupled between an example bolster plate 2122 on the top surface 2116 of the PCB 2118 and an example backplate 2124 on an example bottom surface 2126 of the PCB 2118. In this example, the backplate 2124, the PCB 2118, and the bolster plate 2122 are coupled together via example fasteners 2128 extending through the backplate 2124, the PCB 2118, and/or the bolster plate 2122. In some examples, the semiconductor device 2108 and/or a combination of the semiconductor device 2108, the socket 2112, and PCB 2118 may correspond to an IC package.

In the illustrated example of FIG. 21, the component stack 2100 includes an example plate (e.g., a rigid plate, a load plate, an integrated load plate and carrier) 2130 constructed in accordance with teachings of this disclosure. The example plate 2130 can serve the function of (e.g., replace) the carrier 1704 in the known component stack 1700 of FIG. 17 (to support the semiconductor device 2108) and also provides structural integrity to the heatsink 2102 (to resist bending or warpage when loaded by forces compressing the components in the component stack). In the illustrated example, the plate 2130 includes a first example surface 2132 to face and/or interface with the base 2106, and a second example surface 2134 to face the bolster plate 2122 and/or the PCB 2118, where the second surface 2134 is opposite the first surface 2132. In this example, the first surface 2132 of the plate 2130 is coupled (e.g., affixed, attached, secured, fastened, connected) to the base 2106. In particular, the plate 2130 is removably coupled (e.g., fastened, affixed) to the base 2106 using one or more example fasteners (e.g., bolts, screws, threaded fasteners) 2136 extending through the plate 2130 and/or the base 2106. In this example, the fasteners 2136 are substantially flush with the second surface 2134 of the plate 2130. In some examples, a different method for coupling the plate 2130 to the base 2106 may be used instead. For example, the plate 2130 can be welded or soldered to the base 2106. and/or an adhesive layer can be provided between the plate 2130 and the base 2106. In some examples, the plate 2130 is coupled to the base 2106 without the use of solder.

In the illustrated example, the plate 2130 includes an example aperture (e.g., an opening, a cutout) 2138 extending between the first and second surfaces 2132, 2134. In this example, the aperture 2138 is centrally positioned in the plate 2130. In some examples, the aperture 2138 can be positioned away from a center of the plate 2130 (e.g., closer to a left or right side of the plate 2130 in FIG. 21). In this example, a size of the aperture 2138 is greater than or equal to a corresponding size of the semiconductor device 2108. In the illustrated example, the semiconductor device 2108 is positioned (e.g., disposed) in the aperture 2138. In this example, the semiconductor device 2108 is coupled to the plate 2130 via one or more example carrier snaps (e.g., retention snaps, clips) 2140 to hold the semiconductor device 2108 in the aperture 2138. In this example, the carrier snaps 2140 are spaced about the aperture 2138. In this example, the plate 2130 is a rigid material (e.g., metal, steel). In some examples, the plate 2130 is a material that is stiffer than a material of the base 2106. In some examples, the base 2106 is aluminum having a modulus of elasticity of approximately 70 gigapascals (GPa), and the plate 2130 is steel having a modulus of elasticity of approximately 200 GPa. In such examples, the stiffness of the plate 2130 is approximately three times the stiffness of the base 2106. In some examples, a different material may be used for the base 2106 (e.g., copper having a modulus of elasticity of approximately 120 GPa, aluminum alloy, copper alloy, etc.) and/or for the plate 2130. In some examples, the plate 2130 is a homogenous material. In some examples, the plate 2130 includes two or more layers coupled and/or formed (e.g., laminated) together. In some such examples, the two or more layers can include different materials. For example, a first layer can be a first metal, and the second layer can be a second metal (e.g., the same as or different from the first metal) or ceramic. In some examples, the carrier snaps 2140 are the same material as the plate 2130 and are integrally formed with the plate 2130. In some examples, the carrier snaps 2140 are coupled (e.g., affixed) to the plate 2130, and the carrier snaps 2140 can be the same material as the plate 2130 or a different material.

In the illustrated example, example springs (e.g., retention springs, load springs) 2142 are implemented in spring-loaded fasteners adjacent the second surface 2134 of the plate 2130 and couplable to posts of the bolster plate 2122 to urge the second surface 2134 toward the bolster plate 2122. Additionally or alternatively, the spring-loaded fasteners are adjacent the base 2106 such that the spring-loaded fasteners extend through holes of the plate 2130, or the spring-loaded fasteners can be adjacent the bolster plate 2122 and couplable to corresponding posts on the base 2106 and/or the plate 2130. Like the springs 1810 of FIG. 18, the springs 2142 in the illustrated example of FIG. 21 are used to urge the semiconductor device 2108 toward the socket 2112 to prevent and/or reduce likelihood of the semiconductor device 2108 decoupling from the socket 2112. However, by coupling the plate 2130 to the base 2106, downward forces (e.g., downward loads) of the springs 2142 are distributed through the plate 2130 across a surface of the base 2106 (e.g., instead of the downward forces being concentrated at sides of the base 2106). Further, when the semiconductor device 2108 is pressed into the socket 2112, upward forces (e.g., upward loads) are generated by the semiconductor device 2108 onto the base 2106 In some examples, by distributing the downward forces across the surface of the base 2106, the plate 2130 reduces variation between the upward and downward forces at the center and sides of the base 2106. Accordingly, the plate 2130 can reduce bending of the base 2106 and, thus, may prevent and/or reduce the likelihood of delamination between the base 2106 and the fins 2104 of the heatsink 2102. In some examples, the plate 2130 also includes alignment features (e.g., as described above in connection with the carrier 1704 of FIG. 17) to facilitate alignment of the plate 2130 to the bolster plate 2122 during assembly of the component stack 2100.

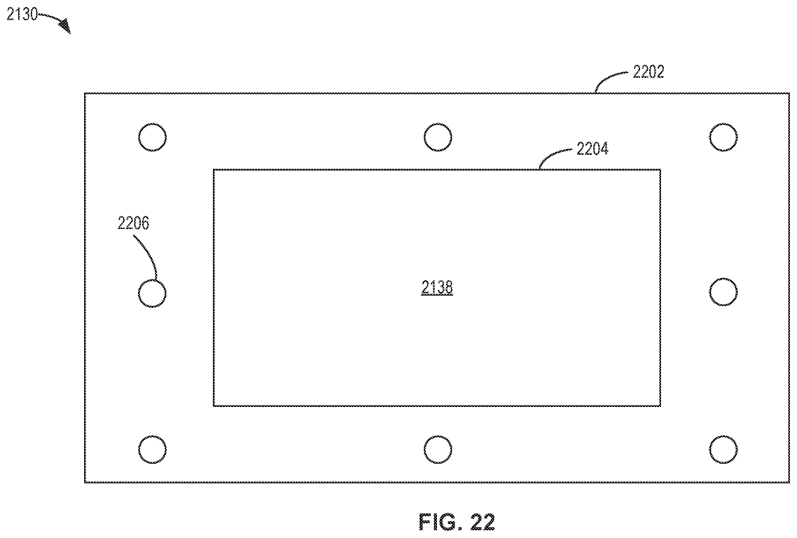

FIG. 22 illustrates a plan view of the example plate 2130 of FIG. 21. In the illustrated example of FIG. 22, the plate 2130 includes an example outer perimeter 2202 and an example inner perimeter 2204 defining the aperture 2138. In some examples, the aperture 2138 is dimensioned to surround the example semiconductor device 2108 of FIG. 21. In the illustrated example, both the outer perimeter 2202 and the aperture 2138 are substantially rectangular. In some examples, at least one of the outer perimeter 2202 or the aperture 2138 is a different shape. In the illustrated example, the plate 2130 includes example holes (e.g., openings, apertures) 2206 spaced around the aperture 2138, where the holes 2206 are to receive the example fasteners 2136 of FIG. 21 to couple the plate 2130 to the base 2106 of FIG. 21. In some examples, the holes 2206 are threaded to enable the use of threaded fasteners for coupling the plate 2130 to the base 2106. In the illustrated example of FIG. 22, eight of the holes 2206 are evenly spaced around the aperture 2138. In some examples, a number and/or spacing of the holes 2206 may be different.

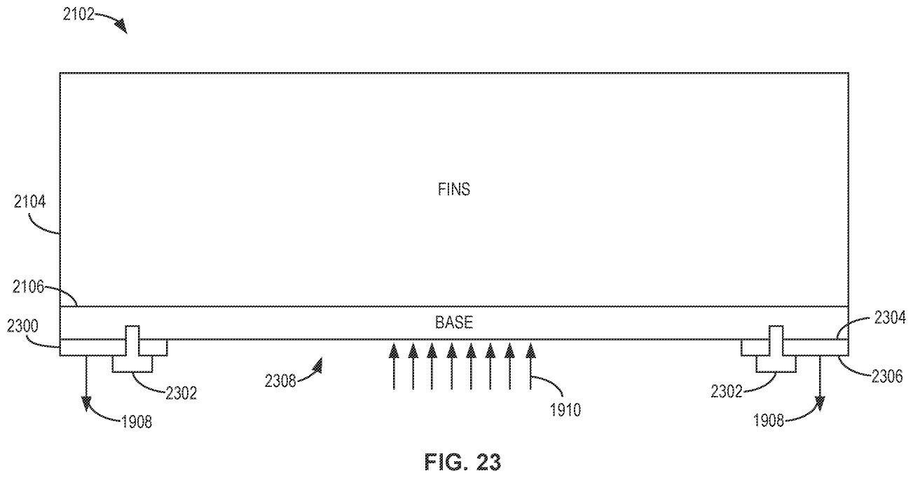

FIG. 23 illustrates an example stiffener plate 2300 that may be implemented in the example component stack 2100 of FIG. 21 in addition to or instead of the example plate 2130 of FIGS. 21 and/or 22. That is, in some examples, the stiffener plate 2300 can be used in combination with a typical carrier (e.g., the carrier 1704) in components stacks that exclude the plate 2130 of FIGS. 21 and/or 22. In other examples, the stiffener plate 2300 can be used in combination with the plate 2130 of FIGS. 21 and/or 22, which may replace the typical carrier 1704. In the illustrated example of FIG. 23, the stiffener plate 2300 is coupled (e.g., affixed, attached, secured, fastened, connected) to the base 2106 of the heatsink 2102 via example fasteners 2302. In this example, the fasteners 2302 extend between first and second example surfaces 2304, 2306 of the stiffener plate 2300, and partially extend into the base 2016. In this example, the fasteners 2302 protrude from the second surface 2306. In some examples, the fasteners 2302 are substantially flush with the second surface 2306. In some examples, the fasteners 2302 include at least one of screws, bolts, threaded fasteners, and/or rivets spaced across the second surface 2306 of the stiffener plate 2300. Additionally or alternatively, the stiffener plate 2300 can be affixed to the base 2106 using a different method of coupling (e.g., soldering, providing an adhesive layer between the stiffener plate 2300 and the base 2106, etc.). In this example, the stiffener plate 2300 is metal (e.g., steel). In some examples, the stiffener plate 2300 is a material that is stiffer than a material of the base 2106. In some examples, the base 2106 is aluminum having a modulus of elasticity of approximately 70 gigapascals (GPa), and the stiffener plate 2300 is steel having a modulus of elasticity of approximately 200 GPa. In such examples, the stiffness of the stiffener plate 2300 is approximately three times the stiffness of the base 2106. In some examples, a different material may be used for the base 2106 (e.g., copper having a modulus of elasticity of approximately 120 GPa, aluminum alloy, copper alloy, etc.) and/or for the stiffener plate 2300. In some examples, the stiffener plate 2300 is a homogenous material. In some examples, the stiffener plate 2300 includes two or more layers coupled and/or formed (e.g., laminated) together. In some such examples, the two or more layers can include different materials. For example, a first layer can be a first metal, and the second layer can be a second metal (e.g., the same as or different from the first metal) or ceramic.

In the illustrated example of FIG. 23, the stiffener plate 2300 includes an example aperture (e.g., an opening, a cutout) 2308 in which the example semiconductor device 2108 of FIG. 21 can be disposed. In some examples, the example springs 2142 of FIG. 21 are implemented in spring-loaded fasteners on the second surface 2306 of the stiffener plate 2300 and/or in spring-loaded fasteners on the base 2106 that extend through the stiffener plate 2300. In some examples, the spring-loaded fasteners including the springs 2142 are couplable to posts on the example bolster plate 2122 of FIG. 21 to urge the second surface 2306 towards the bolster plate 2122, thus facilitating retention of the semiconductor device 2108 in the socket 2112 of FIG. 21. In such examples, the springs 2142 of the spring-loaded fasteners produce the downward forces 1908 proximate sides of the stiffener plate 2300. Further, the semiconductor device 2108 produces the upward forces 1910 on the base 2106 as described in connection with FIGS. 20 and/or 21 above. In contrast to the example plate 2130 of FIGS. 21 and/or 22, the stiffener plate 2300 of FIG. 23 does not include the carrier snaps 2140 of FIG. 21 to couple the semiconductor device 2108 to the stiffener plate 2300. In this example, the stiffener plate 2300 of FIG. 23 increases stiffness of the base 2106 of the heatsink 2102, thereby increasing a resistance of the base 2106 to bending caused by the upward and downward forces 1908, 1910. Accordingly, the stiffener plate 2300 prevents and/or reduces a likelihood of delamination between the base 2106 and the fins 2104 of the heatsink 2102. In some examples, while the example plate 2130 of FIGS. 21 and/or 22 can be used in place of the example carrier 1704 in the component stack 1700 of FIG. 17, the stiffener plate 2300 can be used in addition to and/or instead of the carrier 1704. For example, the stiffener plate 2300 can be coupled between the heatsink 1702 and the carrier 1704 in the example component stack 1700 of FIG. 17.

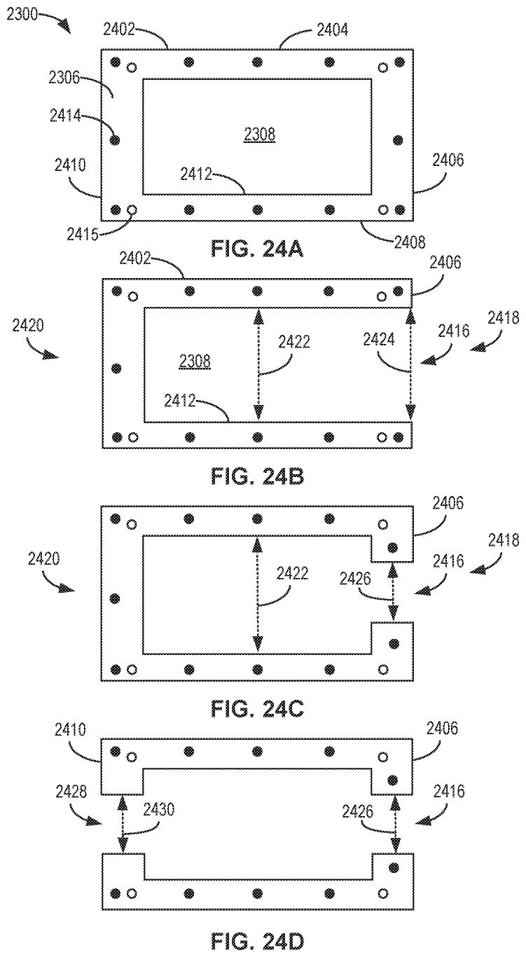

FIGS. 24A, 24B, 24C, and 24D illustrate plan views of the example stiffener plate 2300 of FIG. 23 having first, second, third, and fourth example cross-sectional shapes, respectively. In the illustrated example of FIG. 24A, the example stiffener plate 2300 includes an example outer perimeter 2402 defined by a first example side 2404, a second example side 2406 adjacent the first side 2404, a third example side 2408 opposite the first side 2404, and a fourth example side 2410 opposite the second side 2406. In this example, the first and third sides 2404, 2408 have a first length, and the second and fourth sides 2406, 2410 have a second length less than the first length. In other words, the outer perimeter 2402 defines a rectangular cross-sectional shape. The stiffener plate 2300 further includes an example inner perimeter 2412 defining the aperture 2308, where the aperture 2308 has a rectangular cross-sectional shape (e.g., similar to the cross-sectional shape of the outer perimeter 2402). In some examples, a different shape of the outer perimeter 2402 and/or the aperture 2308 may be used instead. In this example, the stiffener plate 2300 includes first example holes 2414 spaced across the second surface 2306, where the first holes 2414 are dimensioned to receive the example fasteners 2302 of FIG. 23. In this example, second example holes 2415 are positioned at respective corners of the stiffener plate 2300, where the second holes 2415 are dimensioned to receive spring-loaded fasteners implementing the springs 2142 of FIG. 21. In this example, twelve of the first holes 2414 and four of the second holes 2415 (e.g., corresponding to four spring-loaded fasteners) are used. In some examples, a different number and/or spacing of the first holes 2414 and/or the second holes 2415 may be used instead.

Turning to FIG. 24B, the stiffener plate 2300 includes a first example opening 2416 along the second side 2406, such that the stiffener plate 2300 is substantially U-shaped with an example open end 2418 and an example closed end 2420. In this example, the first opening 2416 extends between the outer perimeter 2402 and the inner perimeter 2412 of the stiffener plate 2300. In this example, the aperture 2308 has a first example width 2422 at a midpoint between the open and closed ends 2418, 2420, and the first opening 2424 has a second example width 2424 that is equal to (e.g., substantially the same as) the first width 2422. Stated differently, opposite sides of the stiffener plate 2300 at the open end 2418 are a same distance apart as the opposite sides of the stiffener plate 2300 at the midpoint between the open and closed ends 2418, 2420.

In FIG. 24C, the stiffener plate 2300 is substantially horseshoe-shaped. For example, the first opening 2416 along the second side 2406 has an example third width 2426 which is less than the first width 2422 and/or the second width 2424 of FIG. 24B. In other words, in FIG. 24C, opposite sides of the stiffener plate 2300 are closer together at the open end 2418 than at the midpoint between the open and closed ends 2418, 2420.

Turning to FIG. 24D, the stiffener plate 2300 includes the first opening 2416 having the third width 2426 along the second side 2406 of the stiffener plate 2300, and further includes a second example opening 2428 along the fourth side 2410 of the stiffener plate 2300. In this example, the second opening 2428 has a fourth example width 2430 which is equal to (e.g., substantially the same as) the third width 2426. In some examples, at least one of the first opening 2416 or the second opening 2428 can have a different width (e.g., equal to the first width 2422 and/or the second width 2424 of FIG. 24B). In some examples, the stiffener plate 2300 can include one or more openings along the first side 2404 and/or the third side 2408 of the stiffener plate 2300 in addition to or instead of the first opening 2416 and/or the second opening 2428. In some examples, by including one or more of the openings 2416, 2428 in the stiffener plate 2300, an amount of material and, thus, a cost required to manufacture the stiffener plate 2300 can be reduced.

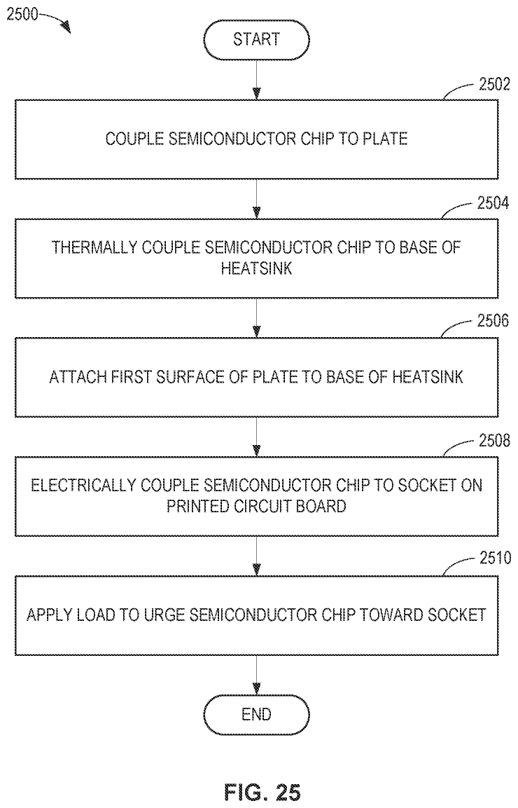

FIG. 25 is a flowchart representative of an example method 2500 of assembling the example component stack 2100 of FIG. 21 with the example plate 2130 of FIG. 21. In some examples, some or all of the operations outlined in the example method 2500 are performed automatically by fabrication equipment that is programmed to perform the operations. Although the example method of manufacturing is described with reference to the flowchart illustrated in FIG. 25, many other methods may alternatively be used. For example, the order of execution of the blocks may be changed, and/or some of the blocks described may be combined, divided, re-arranged, omitted, eliminated, and/or implemented in any other way.

The example method 2500 of FIG. 25 begins at block 2502 by coupling the example semiconductor device 2108 of FIG. 21 to the example plate 2130. For example, the semiconductor device 2108 is positioned (e.g., disposed) in the example aperture 2138 of the plate 2130, and the semiconductor device 2108 is coupled to (e.g., supported adjacent) the plate 2130 via the example carrier snaps 2140 spaced about the aperture 2138.

At block 2504, the example method 2500 includes thermally coupling the example semiconductor device 2108 to the example base 2106 of the example heatsink 2102 of FIG. 21. For example, the semiconductor device 2108 is thermally coupled to the base 2106 via the example TIM 2110 of FIG. 21 to facilitate heat transfer from the semiconductor device 2108 to the base 2106.

At block 2506, the example method 2500 includes attaching (e.g., fastening, securing) the first example surface 2132 of the plate 2130 to the example base 2106 of the heatsink 2102. For example, the first surface 2132 of the plate 2130 to the base 2106 of the heatsink 2102 via the example fasteners 2136 extending through the plate 2130 and/or the base 2106. In some examples, a different method (e.g., soldering, providing an adhesive layer between the first surface 2132 and the base 2106) may be used instead to couple the plate 2130 to the base 2106.

At block 2508, the example method 2500 includes electrically coupling the semiconductor device 2108 to the example socket 2112 of the example PCB 2118 of FIG. 21. For example, the pins 2114 of the socket 2112 are aligned with corresponding contacts on the semiconductor device 2108 to electrically couple the semiconductor device 2108 to the socket 2112.

At block 2510, the example method 2500 includes applying a load to urge the semiconductor device 2108 toward the socket 2112. For example, the springs 2142 generate a load on the base 2106 of the heatsink 2102 and/or the plate 2130 to urge the base 2106 and/or the plate 2130 toward the socket 2112 and, thus, facilitate retention of the semiconductor device 2108 in the socket 2112. In some examples, the plate 2130 distributes loads from the semiconductor device 2108 and/or the springs 2142 across the base 2106 to reduce bending thereof and, thus, prevent and/or reduce a likelihood of delamination between the base 2106 and the example fins 2104 of the heatsink 2102.

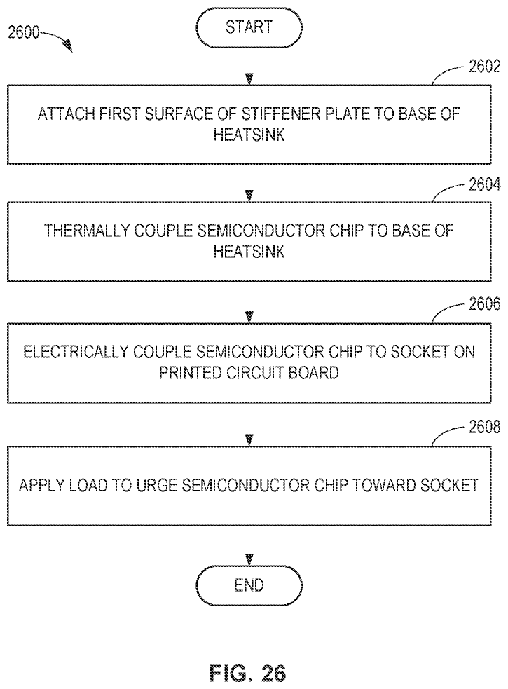

FIG. 26 is a flowchart representative of an example method 2600 of assembling the example component stack 2100 of FIG. 21 with the example stiffener plate 2300 of FIG. 23. In some examples, some or all of the operations outlined in the example method 2600 are performed automatically by fabrication equipment that is programmed to perform the operations. Although the example method of manufacturing is described with reference to the flowchart illustrated in FIG. 26, many other methods may alternatively be used. For example, the order of execution of the blocks may be changed, and/or some of the blocks described may be combined, divided, re-arranged, omitted, eliminated, and/or implemented in any other way.

The example method 2600 of FIG. 26 begins at block 2602 by attaching the first example surface 2304 of the stiffener plate 2300 to the example base 2106 of the example heatsink of FIG. 21. For example, the first surface 2304 of the stiffener plate 2300 is attached (e.g., fastened, secured) to the base 2106 of the heatsink 2102 via the example fasteners 2302 of FIG. 23 extending through the plate 2130 and at least partially through the base 2106. In some examples, a different method (e.g., soldering, providing an adhesive layer between the first surface 2304 and the base 2106) may be used instead to couple the stiffener plate 2300 to the base 2106.

At block 2604, the example method 2600 includes thermally coupling the example semiconductor device 2108 of FIG. 21 to the base 2106 of the heatsink 2102. For example, the semiconductor device 2108 is positioned in the example aperture 2308 of the example stiffener plate 2300, and the semiconductor device 2108 is thermally coupled to the base 2106 via the example TIM 2110 of FIG. 21 to facilitate heat transfer from the semiconductor device 2108 to the base 2106. In some examples, the semiconductor device 2108 is disposed in and/or coupled to the carrier 1704 of FIG. 17 or the plate 2130 of FIG. 21, and the carrier 1704 or the plate 2130 is coupled to the stiffener plate 2300 to thermally couple the semiconductor device 2108 to the base 2106.

At block 2606, the example method 2600 includes electrically coupling the semiconductor device 2108 to the example socket 2112 of the example PCB 2118 of FIG. 21. For example, the pins 2114 of the socket 2112 are aligned with corresponding contacts on the semiconductor device 2108 to electrically couple the semiconductor device 2108 to the socket 2112.

At block 2608, the example method 2600 includes applying a load to urge the semiconductor device 2108 toward the socket 2112. For example, the springs 2142 generate a load on the base 2106 of the heatsink 2102 and/or the stiffener plate 2300 to urge the base 2106 and/or the stiffener plate 2300 toward the socket 2112 and, thus, facilitate retention of the semiconductor device 2108 in the example socket 2112 of FIG. 21. In some examples, the stiffener plate 2300 increases stiffness of the base 2106 to reduce bending caused by the example downward forces 1908 from the springs 2142. Thus, the stiffener plate 2300 prevents and/or reduces a likelihood of delamination between the base 2106 and the example fins 2104 of the heatsink 2102.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that control load distribution of IC packages when assembled within heat dissipating component stacks. Disclosed systems, methods, apparatus, and articles of manufacture provide a plate between a semiconductor device and a heatsink thermally coupled to the semiconductor device. In examples disclosed herein, the plate increases stiffness of a base of the heatsink and/or distributes loads (e.g., retention spring load and/or semiconductor device load) across a surface of the base to reduce bending of the base and, thus, prevent and/or reduce a likelihood of delamination between the base and fins of the heatsink. Furthermore, by reducing and/or preventing delamination between the base and the fins, disclosed systems, methods, apparatus, and articles of manufacture improve the efficiency of using a computing device by maintaining efficient heat transfer from the semiconductor device to the heatsink, thus preventing the semiconductor device from overheating. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to control load distribution of IC packages are disclosed herein. Further examples and combinations thereof include the following:

Example 1 includes an apparatus comprising a heatsink, a base of the heatsink to be thermally coupled to a semiconductor device, and a rigid plate to be coupled to the semiconductor device and the base of the heatsink, the rigid plate stiffer than the base, the rigid plate distinct from a bolster plate to which the heatsink is to be coupled.

Example 2 includes the apparatus of example 1, wherein the rigid plate is metal.

Example 3 includes the apparatus of example 1, wherein the rigid plate is to be removably coupled to the base of the heatsink using at least one of screws or bolts.

Example 4 includes the apparatus of example 1, wherein the rigid plate includes an aperture centrally positioned in the rigid plate, the semiconductor device to be disposed in the aperture.

Example 5 includes the apparatus of example 4, further including carrier snaps spaced about the aperture, the carrier snaps to hold the semiconductor device in the aperture.

Example 6 includes the apparatus of example 5, wherein the carrier snaps are integrally formed with the rigid plate.

Example 7 includes the apparatus of example 1, wherein the rigid plate is to be coupled to the base of the heatsink without solder.

Example 8 includes the apparatus of example 1, wherein the rigid plate is to distribute a load from the semiconductor device to the base of the heatsink when the semiconductor device is pressed into a corresponding socket.

Example 9 includes an apparatus comprising a plate to be coupled to a base of a heatsink, the plate to be stiffer than the base, and an integrated circuit (IC) package to be disposed in an aperture of the plate and thermally coupled to the base of the heatsink, the IC package to extend farther away from the base of the heatsink than the plate extends away from the base of the heatsink.

Example 10 includes the apparatus of example 9, wherein the aperture is centrally positioned in the plate.

Example 11 includes the apparatus of example 10, wherein a first length of a first side of the plate is greater than a second length of a second side of the plate, the first side adjacent the second side, the plate including an opening along the second side.

Example 12 includes the apparatus of example 11, wherein the aperture has a first width and the opening has a second width that is less than the first width.

Example 13 includes the apparatus of example 11, wherein the aperture has a first width and the opening has a second width that is approximately equal to the second width.

Example 14 includes the apparatus of example 9, wherein the plate is U-shaped with an open end and a closed end.

Example 15 includes the apparatus of example 14, wherein opposite sides of the plate at the open end are a same distance apart as the opposite sides of the plate at a midpoint between the open end and the closed end.

Example 16 includes the apparatus of example 14, wherein opposite sides of the plate are closer together at the open end than at a midpoint between the open end and the closed end.

Example 17 includes the apparatus of example 9, wherein the plate is removably couplable to the base of the heatsink using threaded fasteners.

Example 18 includes the apparatus of example 17, wherein the threaded fasteners are spaced around the aperture.

Example 19 includes the apparatus of example 9, further including springs to urge the plate towards a bolster plate of a printed circuit board.

Example 20 includes the apparatus of example 19, wherein the plate is rectangular, the springs to act on the plate at respective corners of the plate.

Example 21 includes an apparatus comprising a first surface to interface with a base of a heatsink, a second surface opposite the first surface, an outer perimeter, an inner perimeter defining an aperture extending between the first and second surfaces, the aperture dimensioned to surround an integrated circuit (IC) package, and one or more holes extending between the first and second surfaces, the one or more holes dimensioned to enable threaded fasteners to secure the apparatus to the base of the heatsink, the apparatus composed of metal.

Example 22 includes the apparatus of example 21, further including one or more carrier snaps spaced around the aperture and couplable to the IC package.

Example 23 includes the apparatus of example 21, wherein the apparatus is U-shaped with a closed end and an open end.

Example 24 includes the apparatus of example 23, wherein the aperture has a first width and an opening at the open end has a second width that is less than the first width.

Example 25 includes the apparatus of example 23, wherein the aperture has a first width and an opening at the open end has a second width, the second width corresponding to the first width.

Example 26 includes a method comprising positioning an integrated circuit (IC) package in an aperture of a metal plate, attaching the metal plate to a base of a heatsink, and thermally coupling the IC package to the base of the heatsink, the metal plate attached to the base of the heatsink prior to coupling of the IC package to a socket of a printed circuit board.

Example 27 includes the method of example 26, wherein the coupling of the metal plate to the base of the heatsink includes fastening the metal plate to the base of the heatsink using at least one of screws or bolts.

Example 28 includes the method of example 27, further including coupling the IC package to the metal plate using carrier snaps affixed to the metal plate.

Example 29 includes the method of example 26, further including applying a load on the metal plate via one or more springs to urge the IC package toward the socket.

Example 30 includes the method of example 29, wherein the metal plate is rectangular, further including positioning the one or more springs to apply the load at respective corners of the metal plate.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus comprising:
a heatsink, a base of the heatsink to be thermally coupled to a semiconductor device; and
a rigid plate to be coupled to the semiconductor device and the base of the heatsink, the rigid plate stiffer than the base, the rigid plate distinct from a bolster plate to which the heatsink is to be coupled.

2. The apparatus of claim 1, wherein the rigid plate is metal.

3. The apparatus of claim 1, wherein the rigid plate is to be removably coupled to the base of the heatsink using at least one of screws or bolts.

4. The apparatus of claim 1, wherein the rigid plate includes an aperture centrally positioned in the rigid plate, the semiconductor device to be disposed in the aperture.

5. The apparatus of claim 4, further including carrier snaps spaced about the aperture, the carrier snaps to hold the semiconductor device in the aperture.

6. The apparatus of claim 5, wherein the carrier snaps are integrally formed with the rigid plate.

7. The apparatus of claim 1, wherein the rigid plate is to be coupled to the base of the heatsink without solder.

8. The apparatus of claim 1, wherein the rigid plate is to distribute a load from the semiconductor device to the base of the heatsink when the semiconductor device is pressed into a corresponding socket.

9. An apparatus comprising:
a plate to be coupled to a base of a heatsink, the plate to be stiffer than the base; and
an integrated circuit (IC) package to be disposed in an aperture of the plate and thermally coupled to the base of the heatsink, the IC package to extend farther away from the base of the heatsink than the plate extends away from the base of the heatsink.

10. The apparatus of claim 9, wherein the aperture is centrally positioned in the plate.

11. The apparatus of claim 10, wherein a first length of a first side of the plate is greater than a second length of a second side of the plate, the first side adjacent the second side, the plate including an opening along the second side.

12. The apparatus of claim 11, wherein the aperture has a first width and the opening has a second width that is less than the first width.

13. The apparatus of claim 11, wherein the aperture has a first width and the opening has a second width that is approximately equal to the second width.

14. The apparatus of claim 9, wherein the plate is U-shaped with an open end and a closed end.

15. The apparatus of claim 14, wherein opposite sides of the plate at the open end are a same distance apart as the opposite sides of the plate at a midpoint between the open end and the closed end.

16. The apparatus of claim 14, wherein opposite sides of the plate are closer together at the open end than at a midpoint between the open end and the closed end.

17. The apparatus of claim 9, wherein the plate is removably couplable to the base of the heatsink using threaded fasteners.

18. The apparatus of claim 17, wherein the threaded fasteners are spaced around the aperture.

19. The apparatus of claim 9, further including springs to urge the plate towards a bolster plate of a printed circuit board.

20. The apparatus of claim 19, wherein the plate is rectangular, the springs to act on the plate at respective corners of the plate.

21. An apparatus comprising:
a first surface to interface with a base of a heatsink;
a second surface opposite the first surface;
an outer perimeter;
an inner perimeter defining an aperture extending between the first and second surfaces, the aperture dimensioned to surround an integrated circuit (IC) package; and
one or more holes extending between the first and second surfaces, the one or more holes dimensioned to enable threaded fasteners to secure the apparatus to the base of the heatsink, the apparatus composed of metal.

22. The apparatus of claim 21, further including one or more carrier snaps spaced around the aperture and couplable to the IC package.

23. The apparatus of claim 21, wherein the apparatus is U-shaped with a closed end and an open end.

24. The apparatus of claim 23, wherein the aperture has a first width and an opening at the open end has a second width that is less than the first width.

25. The apparatus of claim 23, wherein the aperture has a first width and an opening at the open end has a second width, the second width corresponding to the first width.

26-30. (canceled)
